(19) United States
(12) Patent Application Publication
(10) Pub. No.: US 2022/0102201 A1
(43) Pub. Date: Mar. 31, 2022

(54) ADDITIVE DAMASCENE PROCESS

(71) Applicant: INTERNATIONAL BUSINESS MACHINES CORPORATION, ARMONK, NY (US)

(72) Inventor: David Abraham, Croton, NY (US)

(21) Appl. No.: 17/035,569

(22) Filed: Sep. 28, 2020

(51) Int. Cl. H01L 21/768; H01L 23/522; H01L 23/532

(52) U.S. Cl. CPC H01L 21/76819; H01L 23/5329; H01L 23/53257; H01L 23/5226

(57) ABSTRACT

An embodiment of the invention may include a method of forming a device and the resulting structure. The method may include forming a first conductive pattern on a first surface of a substrate. The method may include depositing a first conformal layer on the first surface of the substrate and the first conductive pattern. The method may include planarizing the first conformal layer so that a top surface of the first conductive pattern is substantially planar to a top surface of the first conformal layer. The method may include forming a first electrical component on the top surface of the first conformal layer in contact with the first conductive pattern. This may enable wiring on different levels as the electrical components, while allowing the first electrical component to be built on a substantially planar surface.

### STATEMENT REGARDING FEDERALLY SPONSORED RESEARCH OR DEVELOPMENT

This invention was made with U.S. Government support. The U.S. Government has certain rights in this invention.

### BACKGROUND

The present invention relates to wiring an electrical device, and more specifically, to creating wiring levels.

Traditionally, wiring of microelectronics has been performed using subtractive processes, such as damascene or dual damascene processes. Such processes work by depositing a dielectric material, removing a portion of the dielectric, and filling the void with a conductive material.

### BRIEF SUMMARY

An embodiment of the invention may include a method of forming a device. The method may include forming a first conductive pattern on a first surface of a substrate. The method may include depositing a first conformal layer on the first surface of the substrate and the first conductive pattern. The method may include planarizing the first conformal layer so that a top surface of the first conductive pattern is substantially planar to a top surface of the first conformal layer. The method may include forming a first electrical component on the top surface of the first conformal layer in contact with the first conductive pattern. This may enable wiring on different levels as the electrical components, while allowing the first electrical component to be built on a substantially planar surface.

An embodiment of the device may include the first conformal layer being a low loss material having a loss tangent of less than 10⁻³. This may improve the performance of sensitive electrical components by reducing electrical loss to the conformal layer.

An embodiment of the device may include the first conformal layer being amorphous silicon. This may improve the performance of sensitive electrical components by reducing electrical loss to the conformal layer.

In an embodiment of the device, the method may include forming a via in a first surface of the substrate, wherein the via only extends partially to a second surface of the substrate, wherein the first surface of the substrate and the second surface of the substrate are opposite surfaces. The method may further include forming a portion of the first conductive pattern in contact with the via. This may enable wiring on the back side of a substrate, thereby reducing noise related to wiring at the first electrical component.

In an embodiment of the device, the method may include removing a portion of the second surface of the substrate to expose the via on the second surface of the substrate.

In an embodiment of the device, the method may include depositing a second conductive pattern on the second surface of the substrate, wherein at least a portion of the second conductive patter is in contact with the exposed surface of the via.

In an embodiment of the device, the method may include depositing a second conformal layer on the second surface of the substrate and the second conductive pattern. In the embodiment the method may further include planarizing the second conformal layer so that a top surface of the second conductive pattern is substantially planar to a top surface of the second conformal layer.

In an embodiment of the device, the method may include forming a second electrical component on the top surface of the second conformal layer in contact with the second conductive pattern.

An embodiment of the device may include a material of the first conductive pattern being niobium.

An embodiment of the device may include a material of the second conductive pattern being niobium.

Another embodiment of the invention may include a device. The device may include a first conductive pattern located on a first surface of a substrate. The device may include a first amorphous silicon layer located on the first surface of the substrate. The exposed surface of the first amorphous silicon layer is substantially coplanar with an exposed surface of the first conductive pattern. The device may include a first electrical component. A portion of the electrical component is located on the first amorphous silicon layer, and wherein a portion of the electrical component is located on the first conductive pattern. This may enable wiring on different levels as the electrical components, while allowing the first electrical component to be built on a substantially planar surface.

An embodiment of the device may include the device having a conductive via extending from the first surface of the substrate to a second surface of the substrate, and wherein the conductive via is in contact with the first conductive pattern. This may enable wiring on the back side of a substrate, thereby reducing noise related to wiring at the first electrical component.

An embodiment of the device may include the device having a second amorphous silicon layer located on the second surface of the substrate, wherein an exposed surface of the second amorphous silicon layer is substantially coplanar with an exposed surface of the second conductive pattern. The device may include a second electrical component, wherein a portion of the electrical component is located on the second amorphous silicon layer, and wherein a portion of the electrical component is located on the second conductive pattern.

### BRIEF DESCRIPTION OF THE DRAWINGS

FIG. 1 represents a cross sectional view depicting a substrate, according to an aspect of an example embodiment.

FIG. 2 represents a cross sectional view depicting a substrate following formation of via holes, according to an aspect of an example embodiment.

FIG. 3 represents a cross sectional view depicting a substrate having conductive vias following filling the via holes, according to an aspect of an example embodiment.

FIG. 4 represents a cross sectional view depicting a substrate following patterning of a conductive material on a top side of the substrate, according to an aspect of an example embodiment.

FIG. 5 represents a cross sectional view depicting a substrate following deposition of a dielectric, according to an aspect of an example embodiment.

FIG. 6 represents a cross sectional view depicting a substrate following planarization of the dielectric with the conductive pattern, according to an aspect of an example embodiment.

FIG. 7 represents a cross sectional view depicting a substrate following thinning of the bottom side of the substrate, according to an aspect of an example embodiment.

FIG. 8 represents a cross sectional view depicting a substrate following forming a conductive pattern on the bottom side of the substrate, according to an aspect of an example embodiment.

FIG. 9 represents a cross sectional view depicting a substrate following deposition of a dielectric on the bottom side of the substrate and planarization with the conductive pattern, according to an aspect of an example embodiment.

FIG. 10 represents a cross sectional view depicting a substrate following forming electrical structures on a top side of the substrate, according to an aspect of an example embodiment.

FIG. 11 represents a cross sectional view depicting a substrate following forming electrical structures on a top and bottom side of the substrate, according to an aspect of an example embodiment.

Elements of the figures are not necessarily to scale and are not intended to portray specific parameters of the invention. For clarity and ease of illustration, dimensions of elements may be exaggerated. The detailed description should be consulted for accurate dimensions. The drawings are intended to depict only typical embodiments of the invention, and therefore should not be considered as limiting the scope of the invention. In the drawings, like numbering represents like elements.

### DETAILED DESCRIPTION

Exemplary embodiments now will be described more fully herein with reference to the accompanying drawings, in which exemplary embodiments are shown. This disclosure may, however, be embodied in many different forms and should not be construed as limited to the exemplary embodiments set forth herein. Rather, these exemplary embodiments are provided so that this disclosure will be thorough and complete and will convey the scope of this disclosure to those skilled in the art. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements. As used herein, the term “same” when used for comparing values of a measurement, characteristic, parameter, etc., such as “the same width,” means nominally identical, such as within industry accepted tolerances for the measurement, characteristic, parameter, etc., unless the context indicates a different meaning. As used herein, the terms “about,” “approximately,” “significantly, or similar terms, when used to modify physical or temporal values, such as length, time, temperature, quantity, electrical characteristics, etc., or when such values are stated without such modifiers, means nominally equal to the specified value in recognition of variations to the values that can occur during typical handling, processing, and measurement procedures. These terms are intended to include the degree of error associated with measurement of the physical or temporal value based upon the equipment available at the time of filing the application, or a value within accepted engineering tolerances of the stated value. For example, the term “about” or similar can include a range of ±8% or 5%, or 2% of a given value. In one aspect, the term “about” or similar means within 10% of the specified numerical value. In another aspect, the term “about” or similar means within 5% of the specified numerical value. Yet, in another aspect, the term “about” or similar means within 10, 9, 8, 7, 6, 5, 4, 3, 2, or 1% of the specified numerical value. In another aspect, these terms mean within industry accepted tolerances.

For the clarity of the description, and without implying any limitation thereto, illustrative embodiments may be described using simplified diagrams. In an actual fabrication, additional structures that are not shown or described herein, or structures different from those shown and described herein, may be present without departing from the scope of the illustrative embodiments.

Differently patterned portions in the drawings of the example structures, layers, and formations are intended to represent different structures, layers, materials, and formations in the example fabrication, as described herein. A specific shape, location, position, or dimension of a shape depicted herein is not intended to be limiting on the illustrative embodiments unless such a characteristic is expressly described as a feature of an embodiment. The shape, location, position, dimension, or some combination thereof, are chosen only for the clarity of the drawings and the description and may have been exaggerated, minimized, or otherwise changed from actual shape, location, position, or dimension that might be used in actual fabrication to achieve an objective according to the illustrative embodiments.

An embodiment when implemented in an application causes a fabrication process to perform certain steps as described herein. The steps of the fabrication process are depicted in the several figures. Unless such a characteristic is expressly described as a feature of an embodiment, not all steps may be necessary in a particular fabrication process; some fabrication processes may implement the steps in different order, combine certain steps, remove or replace certain steps, or perform some combination of these and other manipulations of steps, without departing the scope of the illustrative embodiments.

The illustrative embodiments are described with respect to certain types of materials, electrical properties, structures, formations, layers orientations, directions, steps, operations, planes, dimensions, numerosity, data processing systems, environments, and components. Unless such a characteristic is expressly described as a feature of an embodiment, any specific descriptions of these and other similar artifacts are not intended to be limiting to the invention; any suitable manifestation of these and other similar artifacts can be selected within the scope of the illustrative embodiments.

The illustrative embodiments are described using specific designs, architectures, layouts, schematics, and tools only as examples and are not limiting to the illustrative embodiments. The illustrative embodiments may be used in conjunction with other comparable or similarly purposed designs, architectures, layouts, schematics, and tools.

For the sake of brevity, conventional techniques related to microelectronic fabrication may or may not be described in detail herein. Moreover, the various tasks and process steps described herein can be incorporated into a more comprehensive procedure or process having additional steps or functionality not described in detail herein. In particular, various steps in the manufacture of microelectronic devices may be well known and so, in the interest of brevity, many conventional steps may only be mentioned briefly or may be omitted entirely without providing the well-known process details.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Conductive structures may be patterned on the surfaces of structures, with a conductive via acting as an electrical conduit between a first surface of a first side of the structure and a second surface of the second side of the structure. While such a raised pattern may be suitable for some applications, other applications may benefit from a substantially planar surface to the patterned conductive structure that can be used as the base to build additional structures, or perform additional processing. Traditional techniques, such as a damascene process, may etch into the conductive via and underlying via structure, and allow for refilling with a conductive material. However, such processes may cause undesired damage to underlying structure, such as by over etching of conductive vias leaving unwanted surface imperfections, which may lead to detrimental outcomes of electrical devices made using those vias. In addition, in a case where the conductive via is prepared as shown in FIG. 3, it may not be possible to then create a damascene trench in the first surface of the wafer without damaging the conductive via, due to differential etch rates of the fill and the substrate material. Additionally, it may not be possible to etch and fill the second surface after the first surface has been prepared.

Thus, a process of creating a damascene-like wiring structure, where only a top surface of the wire is exposed so that the top surface of a wiring layout is substantially planar with other structures on that level of the device, may improve aspects of fabrication and performance of a resulting device. In some embodiments, such structures may benefit from having a surface that is substantially similar, chemically, to the substrate carrying the conductive vias. This may allow for processing of the entire stack at the same time. It also may be advantageous to have the top surface include a low-loss material, where electrical loss in the dielectric surface at the frequencies of interest as regards the device operation are reduced compared to other materials.

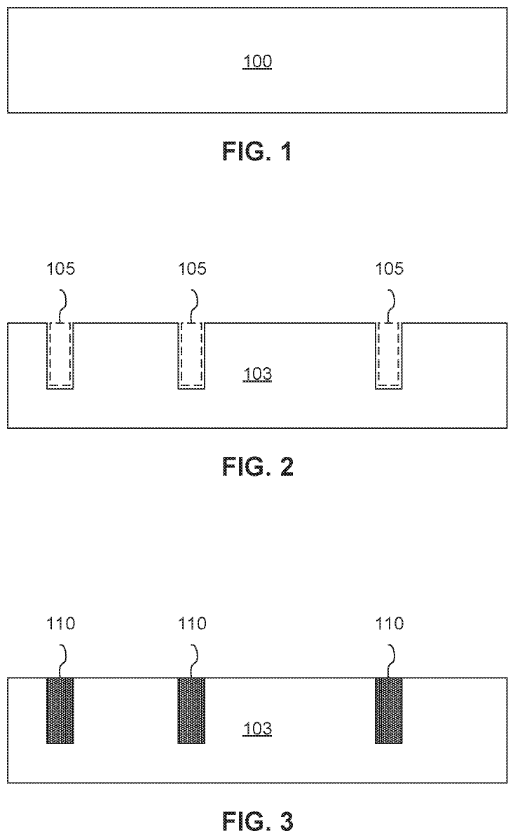

Referring to FIG. 1, a substrate 100 is provided. The substrate 100 may be a dielectric material. The substrate 100 may be any material suitable for handling the processing and operational requirements of electrical structures built into and/or on top of the substrate. In an embodiment, substrate 100 may be made from materials such as, for example, Si, Ge, Sapphire or Quartz.

Referring to FIG. 2, via holes 105 may be created in the substrate 100, forming base layer 103. The via holes 105 may be created using mechanical, chemical or laser techniques. The via holes 105 may be spaced such that they align with the placement of vias in subsequent steps. In one embodiment, a mechanical drill may be used to create each via hole 105, starting on one surface of the substrate 100, and extending toward the opposite surface of the substrate 100. Additional embodiments may use techniques such as laser ablation, or patterning and etching the unpatterned portions of the substrate 100 to form each via hole 105.

Referring to FIG. 3, each via hole 105 may be filled with a conductive via 110. The conductive vias 110 contains a metal fill which may be deposited in via hole 105. In some embodiments, a liner and dielectric may be deposited prior to depositing the metal fill. The liner may be made of, for example, tantalum, tantalum nitride, titanium, or titanium nitride, as an adhesion layer for subsequent deposition, and may include one or more layers of liner material. The metal fill may include, for example, copper, aluminum, niobium, or tungsten. The liner and metal fill may be formed using a filing technique such as electroplating, electroless plating, chemical vapor deposition, physical vapor deposition, atomic layer deposition or a combination of methods.

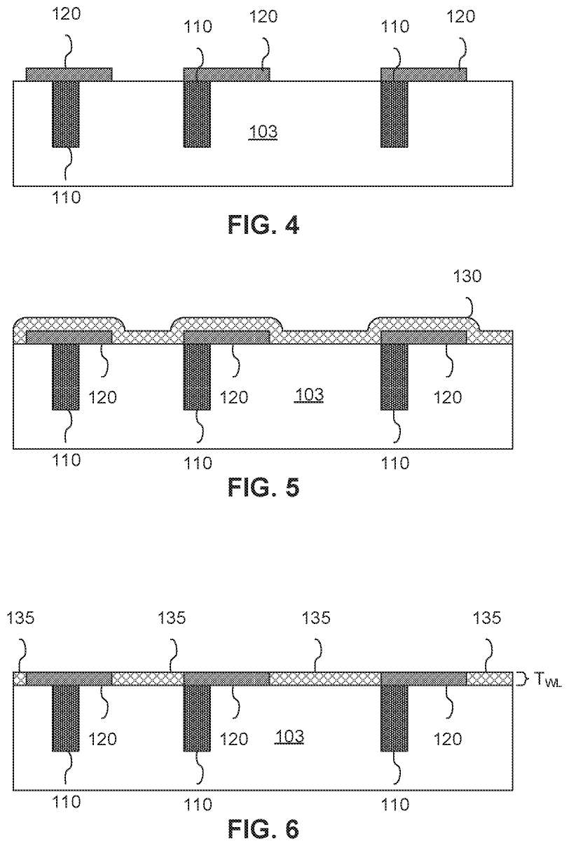

Referring to FIG. 4, a top conductive pattern 120 is deposited and patterned on the base layer 103. The top conductive pattern 120 may be deposited using any number of techniques such as, for example, electroplating, evaporation, or sputtering. The pattern applied may include surface wiring leading to logical structures of a device. In one embodiment, a photolithographic pattern may be applied to the surface of the top conductive pattern 120, and an anisotropic process, such as, for example, reactive ion etching (RIE), plasma etching, or an isotropic process such as a wet etch may be used to remove a portion of the material. In another embodiment, laser ablation may be used to remove unwanted portions of the top conductive pattern 120. The top conductive pattern 120 may be made of any suitable conductive material such as, for example, copper, aluminum, tungsten, niobium or any other suitable material, in accordance with an embodiment of the invention.

Referring to FIG. 5, a conformal layer 130 of a isolating material may be deposited above base layer 103, conductive via 110, and the top conductive pattern 120. More specifically, the method may include conformally depositing layer 130 directly on the exposed surfaces of base layer 103, conductive via 110, and the top conductive pattern 120. The conformal layer 130 may include any material capable of electrically isolating non-contiguous portions of the top conductive pattern 120. For example, the conformal layer 130 may be a low loss material having a loss tangent of less than 10⁻³. In this instance, the loss tangent is defined as the angle between the impedance vector and the negative reactive axis. In an embodiment, the conformal layer 130 may contain amorphous silicon. In another embodiment, the conformal layer 130 may include, for example, GaAs, silicon nitride, or silicon oxide. In an embodiment, the material for the conformal layer 130 may be selected to substantially match that of the base layer 103, such that processing steps may be employed on both layers and with similar processing impacts. The conformal layer 130 may be deposited with a conformal deposition technique, using any known atomic layer deposition technique, molecular layer deposition techniques, evaporation, sputtering or future developed deposition technique, in accordance with an embodiment of the invention. In one embodiment, the conformal layer 130 may have a substantially uniform thickness.

Referring to FIG. 6, a raised portion of the conformal layer 130, located above top conductive pattern 120, may be removed, leaving a top inter-wiring material 135. The top conductive pattern 120 and top inter-wiring material 135 may form a top wiring layer, T_{WL}. The raised portion of the conformal layer 130 may be removed using, for example, a chemical mechanical polishing (CMP) technique. This may create a planar, or substantially planar, surface of the top wiring layer T_{WL}. In this embodiment, non-contiguous portions of the top conductive pattern 120 of top wiring layer T_{WL} may be substantially, and/or practically, isolated from each other by the top inter-wiring material 135.

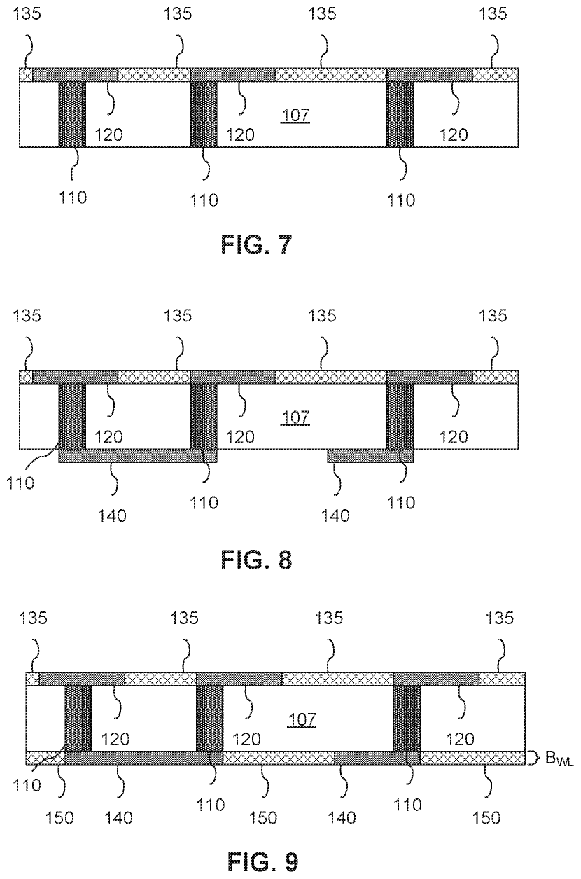

Referring to FIG. 7, a back side of base layer 103 may be removed or thinned, forming substrate 107 having a back surface and exposing the conductive via 110. Thinning of the base layer 103 may be performed using CMP.

Referring to FIG. 8, a bottom conductive pattern 140 may be formed on the back surface of the substrate 107. The bottom conductive pattern 140 may be deposited using any number of techniques such as, for example, electroplating. The pattern applied may include surface wiring leading to logical structures of a device. In one embodiment, a photolithographic pattern may be applied to the surface of the bottom conductive pattern 140, and an anisotropic process, such as, for example, reactive ion etching (RIE), plasma etching, or an isotropic process such as a wet etch may be used to remove a portion of the material. In another embodiment, laser ablation may be used to remove unwanted portions of the bottom conductive pattern 140. The bottom conductive pattern 140 may be made of any conductive material such as, for example, copper, aluminum, tungsten, niobium or any other suitable material, in accordance with an embodiment of the invention. The bottom conductive pattern 140 may be deposited using any number of techniques such as, for example, electroplating.

Referring to FIG. 9, optionally a bottom inter-wiring material 150 may be formed, similarly to the steps performed in FIGS. 5 and 6, thereby creating a bottom wiring level, B_{WL}, with the bottom conductive pattern 140. The method may include conformally depositing a layer of material on the exposed surfaces of conductive via 110, the bottom conductive pattern 140 and the substrate 107. The conformal layer may include any material capable of electrically isolating non-contiguous portions of the bottom conductive pattern 140, in accordance with an embodiment of the invention. In an embodiment, the conformal layer may contain amorphous silicon or GaAs. In another embodiment, the conformal layer may include, for example, silicon nitride or silicon oxide. In an embodiment, the material for the conformal layer may be selected to substantially match that of the substrate 107, such that processing steps may be employed on both layers and with similar processing impacts. The conformal layer may be deposited with a conformal deposition technique, using any known atomic layer deposition technique, molecular layer deposition techniques, or future developed deposition technique, in accordance with an embodiment of the invention. In one embodiment, the conformal layer may have a substantially uniform thickness. In one embodiment, the conformal layer may have a conformal and uniform thickness ranging from about 5 nm to about 50 nm. An elevated portion of the conformal layer, covering bottom conductive pattern 140, may be removed, leaving a bottom inter-wiring material 150. The elevated portion of the conformal layer may be removed using, for example, a chemical mechanical polishing (CMP) technique. This may create a planar, or substantially planar, surface of the bottom wiring level B_{WL}. In this embodiment, non-contiguous portions of the bottom conductive pattern 140 of the bottom wiring level B_{WL} may be substantially, and/or practically, isolated from each other by the bottom inter-wiring material 150.

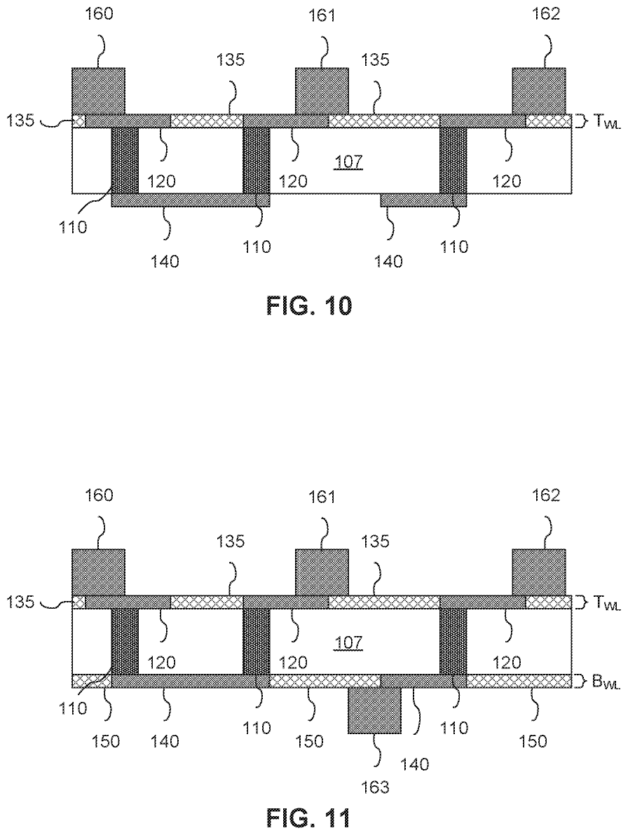

Referring to FIGS. 10 and 11, a first top structure 160, a second top structure 161, and a third top structure 162 may be formed on the top wiring layer T_{WL} in the embodiments depicted in FIGS. 8 and 9, respectively. FIG. 11 depicts a first bottom structure 163 formed on the bottom wiring layer B_{WL} of the embodiment depicted in FIG. 9. The first top structure 160, second top structure 161, third top structure 162, and first bottom structure 163 may be any electrical structure, or secondary wiring, that may need to be electrically connected. Electrical structures may include one or more capacitors, resistors, transistors, inductors, sensors, antennas, amplifiers, diodes, switches, fuses, Josephson junctions, memory, pins, bump bonds, or any other electrical component or connection, alone or in combination with each other, used in creating electrical circuits.

Referring to FIG. 10, a structure is formed having a first top structure 160, a second top structure 161, and a third top structure 162 located on a top wiring layer T_{WL}. The top wiring layer contains a wiring layout, depicted as top conductive pattern 120, isolated from other conductive aspects by top inter-wiring material 135. The top conductive pattern 120 may be electrically connected to a bottom conductive pattern 140, located on the opposite surface of substrate 107, through a conductive via 110. In an embodiment, only a single wiring layer, top wiring layer T_{WL}, is located on the top surface of substrate 107. In an embodiment, the top inter-wiring material 135 may be amorphous silicon, while the substrate 107 is crystalline silicon. This matching material types may enable more efficient processing between the top wiring layer T_{WL} and the substrate 107. Additionally, using an amorphous or poly-crystalline silicon as the top inter-wiring material 135 may reduce microwave loss from the wiring and structures located adjacent to the top inter-wiring material 135. Other low-loss semiconductors such as GaAs could also be used to create the top inter-wiring material 135.

Referring to FIG. 11, a structure is formed having a first top structure 160, a second top structure 161, and a third top structure 162 located on a top wiring layer T_{WL}. The top wiring layer contains a wiring layout, depicted as top conductive pattern 120, isolated from other conductive aspects by top inter-wiring material 135. The top conductive pattern 120 may be electrically connected to a bottom conductive pattern 140, located on the opposite surface of substrate 107, through a conductive via 110. The bottom conductive pattern 140 may be located in a bottom wiring layer B_{WL}, which contains a bottom inter-wiring material 150. The bottom inter-wiring material 150 isolates non-contiguous elements of the bottom conductive pattern 140. Additionally, a bottom structure 163 may be located on the surface of the bottom wiring layer B_{WL}. In an embodiment, only a single wiring layer, top wiring layer T_{WL}, is located on the top surface of substrate 107. In an embodiment, only a single wiring layer, bottom wiring layer B_{WL}, is located on the bottom surface of substrate 107. In an embodiment, the top inter-wiring material 135 and bottom inter-wiring material 150 may be amorphous silicon, while the substrate 107 is crystalline silicon. This matching material types may enable more efficient processing between the top wiring layer T_{WL}, bottom wiring layer B_{WL} and the substrate 107. Additionally, using a low-loss dielectric material such as amorphous silicon as the top inter-wiring material 135 and bottom inter-wiring material 150 may reduce microwave loss from the wiring and structures located adjacent to the top inter-wiring material 135 and bottom inter-wiring material 150. In some embodiments, aspects of functioning of the bottom structure 163 may impact the performance of the first top structure 160, the second top structure 161, and/or the third top structure 162, or vice-versa, so isolation of the components by the substrate 107 may reduce such interference of components.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable other of ordinary skill in the art to understand the embodiments disclosed herein. It is therefore intended that the present invention not be limited to the exact forms and details described and illustrated but fall within the scope of the appended claims.

What is claimed is:

1. A method of forming a device comprising:
forming a first conductive pattern on a first surface of a substrate;
depositing a first conformal layer on the first surface of the substrate and the first conductive pattern;
planarizing the first conformal layer so that a top surface of the first conductive pattern is substantially planar to a top surface of the first conformal layer; and
forming a first electrical component on the top surface of the first conformal layer in contact with the first conductive pattern.

2. The method of forming the device of claim 1, wherein the first conformal layer is a low loss material, wherein the low loss material has a loss tangent less than 10⁻³.

3. The method of forming the device of claim 1, wherein the first conformal layer is amorphous silicon.

4. The method of forming the device of claim 1 further comprising:
prior to forming the first conductive pattern, forming a via in a first surface of the substrate, wherein the via only extends partially to a second surface of the substrate, wherein the first surface of the substrate and the second surface of the substrate are opposite surfaces; and
wherein forming the first conductive pattern comprises forming a portion of the first conductive pattern in contact with the via.

5. The method of forming the device of claim 4 further comprising removing a portion of the second surface of the substrate to expose the via on the second surface of the substrate.

6. The method of forming the device of claim 5 further comprising depositing a second conductive pattern on the second surface of the substrate, wherein at least a portion of the second conductive patter is in contact with the exposed surface of the via.

7. The method of forming the device of claim 6 further comprising depositing a second conformal layer on the second surface of the substrate and the second conductive pattern;
planarizing the second conformal layer so that a top surface of the second conductive pattern is substantially planar to a top surface of the second conformal layer.

8. The method of forming the device of claim 7 further comprising forming a second electrical component on the top surface of the second conformal layer in contact with the second conductive pattern.

9. The method of forming the device of claim 1, wherein a material of the first conductive pattern comprises niobium.

10. The method of forming the device of claim 7, wherein a material of the second conductive pattern comprises niobium.

11. A method of forming a device comprising:
forming a first niobium pattern on a first surface of a substrate;
depositing a first amorphous silicon layer on the first surface of the substrate and the first niobium pattern;
planarizing the first amorphous silicon layer so that a top surface of the first niobium pattern is substantially planar to a top surface of the first amorphous silicon layer; and
forming a first electrical component on the top surface of the first amorphous silicon layer in contact with the first niobium pattern.

12. The method of forming the device of claim 11 further comprising:
prior to forming the first niobium pattern, forming a via in a first surface of the substrate, wherein the via only extends partially to a second surface of the substrate, wherein the first surface of the substrate and the second surface of the substrate are opposite surfaces; and
wherein forming the first niobium pattern comprises forming a portion of the first niobium pattern in contact with the via.

13. The method of forming the device of claim 12 further comprising removing a portion of the second surface of the substrate to expose the via on the second surface of the substrate.

14. The method of forming the device of claim 13 further comprising depositing a second niobium pattern on the second surface of the substrate, wherein at least a portion of the second conductive patter is in contact with the exposed surface of the via.

15. The method of forming the device of claim 14 further comprising depositing a second amorphous silicon layer on the second surface of the substrate and the second niobium pattern;
planarizing the second amorphous silicon layer so that a top surface of the second niobium pattern is substantially planar to a top surface of the second amorphous silicon layer.

16. The method of forming the device of claim 16 further comprising forming a second electrical component on the top surface of the second conformal layer in contact with the second niobium pattern.

17. A device comprising:
a first conductive pattern located on a first surface of a substrate;
a first amorphous silicon layer located on the first surface of the substrate, wherein an exposed surface of the first amorphous silicon layer is substantially coplanar with an exposed surface of the first conductive pattern; and
a first electrical component, wherein a portion of the electrical component is located on the first amorphous silicon layer, and wherein a portion of the electrical component is located on the first conductive pattern.

18. The device of claim 17 further comprising a conductive via extending from the first surface of the substrate to a second surface of the substrate, and wherein the conductive via is in contact with the first conductive pattern.

19. The device of claim 18 further comprising:
a second amorphous silicon layer located on the second surface of the substrate, wherein an exposed surface of the second amorphous silicon layer is substantially coplanar with an exposed surface of the second conductive pattern; and
a second electrical component, wherein a portion of the electrical component is located on the second amorphous silicon layer, and wherein a portion of the electrical component is located on the second conductive pattern.
